(19) United States
(12) Patent Application Publication
(10) Pub. No.: US 2005/0121769 A1
(43) Pub. Date: Jun. 9, 2005

(54) Stacked integrated circuit packages and methods of making the packages

(76) Inventors: Nicholas R. Watts, Phoenix, AZ (US); Eric C. Palmer, Tempe, AZ (US); Jui Min Lim, Chandler, AZ (US); Todd B. Myers, Gilbert, AZ (US); Boonsri Wangmaneerat, Chandler, AZ (US)

Correspondence Address: Buckley, Maschoff & Talwalkar LLC, Five Elm Street, New Canaan, CT, 06840, US

(21) Appl. No.: 10/729,544

(22) Filed: Dec. 5, 2003

(51) Int. Cl. H01L 23/04; H01L 21/44

(52) U.S. Cl. 257/698; 257/686; 438/109; 257/688; 438/117

(57) ABSTRACT

In some embodiments, a method includes providing a substrate, providing a coverlay blank, laminating the coverlay blank to the substrate, and forming at least one opening in the coverlay blank by photolithography.

### BACKGROUND

Stacked integrated circuit (IC) packages have been proposed, in which two or more ICs are housed in a stacked configuration within a single package. While such an arrangement may reduce the footprint of electronics that incorporate the ICs, the overall height of the package may be so great as to require trade-offs. In addition, manufacture of such a stacked package, or manufacture of components thereof, may present complexities that may lead to increased manufacturing costs.

### BRIEF DESCRIPTION OF THE DRAWINGS

FIG. 1 is a schematic side cross-sectional view of an IC package component according to some embodiments.

FIG. 2 is a flow chart that illustrates at least some of a process according to some embodiments for manufacturing the IC package component of FIG. 1.

FIG. 3 is a flow chart that illustrates at least some of a process according to some other embodiments for manufacturing the IC package component of FIG. 1.

FIG. 4 is a schematic side cross-sectional view of a stacked IC package according to some embodiments, incorporating several IC package components like that shown in FIG. 1.

FIG. 5 is block diagram of an electronic apparatus that includes the stacked IC package of FIG. 4.

### DETAILED DESCRIPTION

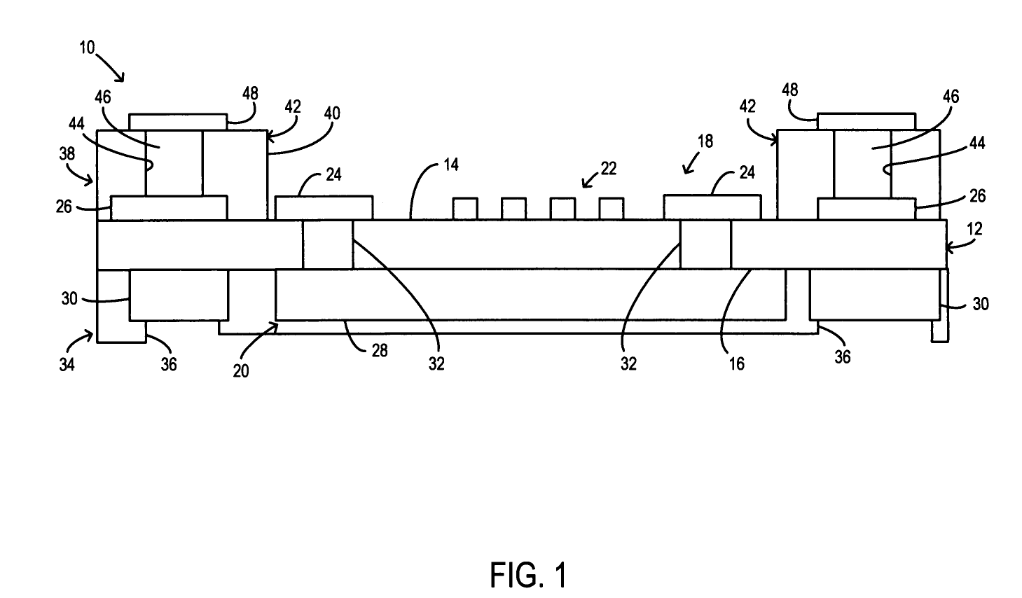

FIG. 1 is a schematic side cross-sectional view of an IC package component 10 according to some embodiments. As will be seen, the package component 10 may be used to construct a stacked IC package, to be described below. In addition, since the package component 10 is itself suitable for having an IC mounted thereto, the package component 10 may be considered to be an IC package in its own right.

The package component 10 includes a substrate 12, which may be formed of a flexible, organic material such as, for example, an acrylic-, urethane- or polyimide-based material or combinations thereof. The substrate 12 has a top surface 14 and a bottom surface 16 that is opposite to the top surface 14. The substrate 12 has a metal layer 18 formed on its top surface 14 and another metal layer 20 formed on its bottom surface 16. The metal layers 18, 20 may both be formed of copper, for example. The metal layer 18 may include signal traces 22. The metal layer 18 may also include pads 24 by which connections may be made to the metal layer 20, and pads 26 by which connection may be made to another IC package component (not shown in FIG. 1) to be discussed below. The metal layer 20 may include a ground plane 28 and pads 30 by which connection may be made to still another IC package component (not shown in FIG. 1) to be discussed below, or to electronic components outside of a stacked package (not shown in FIG. 1) that may be constructed with the package component 10. The substrate 12 may also include metallized vias 32 to provide connections between metal layers 18, 20.

A solder mask layer 34 may also be provided on the bottom surface 16 of the substrate 12. The solder mask layer 34 may completely cover the ground plane 28 and all non-metallized portions of the bottom surface of the substrate 12, while having openings 36 to leave at least some portion of the pads 30 exposed, so that solder (not shown in FIG. 1) may be applied only to the pads 30, to form, for example, solder balls for a ball grid assembly (BGA).

The package component 10 also includes a coverlay 38 that is laminated to the top surface 14 of the substrate 12. The coverlay 38 may, in some embodiments, be formed of substantially the same material as the substrate 12. For example, the coverlay may be formed of a flexible, organic material, such as an acrylic-, urethane- or polyimide-based material or combinations thereof. As will be seen, the coverlay may function as an interposer to accommodate an IC (not shown in FIG. 1) to be mounted on the top surface 14 of the substrate 12. Thus, the coverlay may have a large central opening 40 between standoff elements 42. The central opening 40, as discussed below, may be formed by a photolithographic process. As part of a process for manufacturing a stacked package with the package component 10, an IC may be placed in the opening 40.

The coverlay may also have openings 44 located at the pads 26 on the substrate 12 to serve as metallized vias for conductive connection from above to the substrate 12. The metal 46 in the openings 44 may, for example, be formed from plated copper or printed solder paste. Metal pads 48 may be provided on the top of the openings 44 to allow for conductive connection from above to the vias formed by the openings 44.

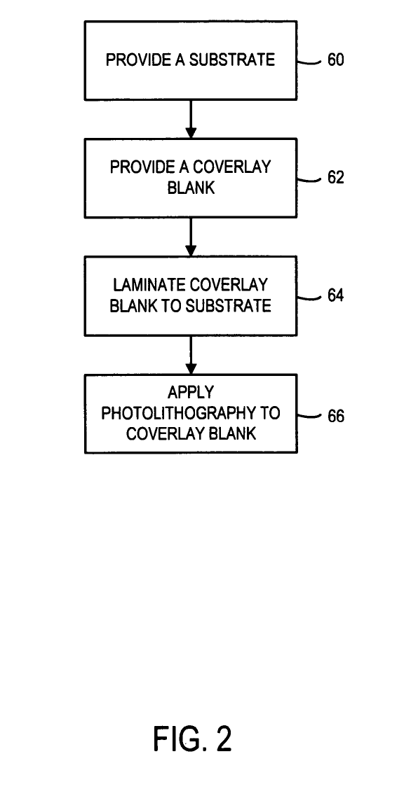

At least part of a process for manufacturing the package component 10 will now be described with reference to FIG. 2.

As indicated at 60 in FIG. 2, the substrate 12 may be provided. In practical embodiments of the process of FIG. 2, providing the substrate 12 may be accomplished by obtaining the substrate 12 from a third party or from another facility, with metal layers 18, 20, vias 32 and solder mask 34 as indicated in FIG. 1. Alternatively, in some embodiments, providing the substrate 12 may entail extensive processing, in a manner which will now be briefly described.

Initially, a sheet of a flexible, organic material (not shown) may be provided with a metal (e.g., copper) coating on both sides. Sprocket holes may be punched along edges of the metal-coated sheet to facilitate handling of the metal-coated sheet on rotary reels for further processing. The sheet may then be washed to remove debris from the punching operation. A layer of photolithographic resist material may then be laminated on both of the metal layers. Next, the resist layer may be exposed to radiation in a suitable pattern to form the vias 32 (FIG. 1), and the resulting image may then be developed. A suitable protective coating may be laid down at the edges of the sheet to protect the sprocket holes from etching. Etching of the metal layers at the loci of the vias may then proceed.

After etching, the resist may be stripped from both sides of the sheet, and then the vias may be opened by laser drilling through the organic material. There then follows a stage in which the via holes are cleaned. Next is an initial metallization of the via holes, followed by copper plating to fill the via holes. Another cleaning stage removes residue left by the plating stage. Next, mechanical polishing is applied to roughen the copper layers.

Once again, a layer of photolithographic resist is laminated to both metal layers. Then the resist on each side of the sheet is exposed to radiation to form suitable patterns to produce the signal traces 22 and pads 24, 26 on one side of the sheet and to produce the ground plane 28 and pads 30 on the other side of the sheet. After developing the exposed resist, etching is performed on both sides, resulting in the aforesaid signal traces 22 and pads 24, 26 on one side of the sheet and ground plane 28 and pads 30 on the other side of the sheet. Excess resist is then stripped from both sides of the sheet.

There follows chemical pre-treatment in preparation for formation of a solder mask (resist) layer on one or both sides of the sheet. In some embodiments, the package component 10 is to have solder mask only on side, i.e. the bottom, as shown in FIG. 1. In other embodiments, another solder mask layer, which is not shown, may also be provided on the top of the substrate 12. If this additional (“underdie”) solder mask layer is to be provided, then a suitable photoimageable solder resist (PSR) is applied to the top surface (i.e., the signal side) of the sheet (over the signal trace pattern). The PSR is then pre-baked, exposed and developed.

Next, a suitable coverlay blank is provided (as indicated at 62 in FIG. 2) and laminated to the top surface (signal side) 14 of the substrate sheet, as indicated at 64 in FIG. 2. The coverlay blank may be a photoimageable, flexible, organic material that may, in some embodiments, be acrylic-, urethane- or polyimide-based.

After the coverlay blank has been laminated to the substrate sheet, laser drilling may be performed to create the via openings 44 shown in FIG. 1. The resulting openings may then be cleaned prior to metallization of the openings to prepare for filling the vias with copper plating. The openings may then be filled by copper plating and at the same time the pads 48 may be formed with copper plating.

After the filling of the via openings 44, other openings, such as the central openings 40, may be formed in the coverlay blank by photolithography, as indicated at 66 in FIG. 2. More specifically, the coverlay blank may be exposed to radiation in a suitable pattern to form the openings 40 and/or other openings. The exposed coverlay blank may then be developed and exposed to a suitable etchant to form the openings 40 and/or other openings. Standoff elements 42 remain after the etching is complete.

Following the drilling, filling and etching of the coverlay blank, PSR may be laminated to the ground side (bottom surface 16) of the substrate 12. The ground side PSR may then be pre-baked, exposed, developed, and post-baked to form the solder mask layer 34. There follows curing by UV radiation of the signal side PSR (if present) and the ground side PSR.

At a following stage, exposed metal regions may be gold and nickel plated. Another post bake may be performed, followed by slitting of the processed sheet into individual package components 10. An inspection stage may then follow.

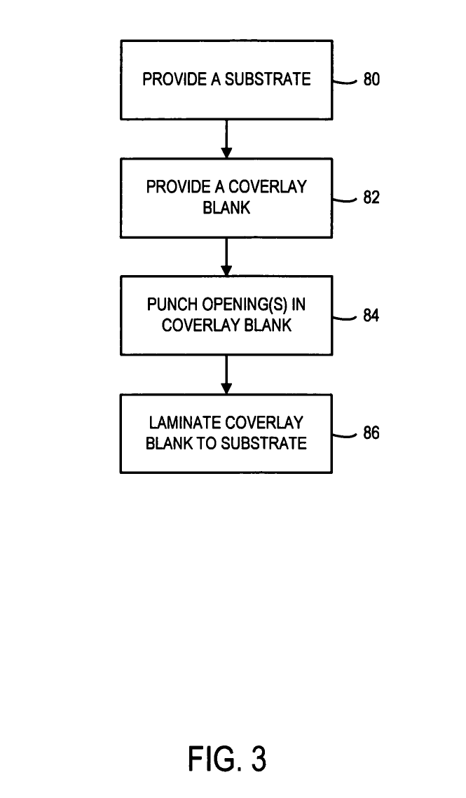

In other embodiments, at least one opening in the coverlay 38 may be formed by punching rather than photolithography. An example of such an alternative process will now be described with reference to FIG. 3.

Initially, or at a later stage, a substrate 12 may be provided, as indicated at 80 in FIG. 3. Also, a coverlay blank may be provided, as indicated at 82 in FIG. 3. The coverlay blank may, for example, be a flexible, organic material, such as an acrylic-, urethane- or polyimide based material. In some embodiments, the substrate may also be of a flexible, organic material, and may be of the same material as the coverlay blank.

As indicated at 84, the coverlay blank may be punched to form openings in the coverlay blank, including for example the openings 40, 44 shown in FIG. 1.

The order of stages shown in FIG. 3 (or in FIG. 2) may be varied, and such stages may be performed in any order that is practicable. For example, considering the process of FIG. 3, the coverlay blank may be provided and punched and then the substrate may be provided.

For example, in providing the substrate, initially a flexible, organic material layer sheet (not shown) may be provided with metal (e.g., copper) coating on both sides. Sprocket holes may be punched along edges of the metal-coated sheet to facilitate handling of the metal-coated sheet on rotary reels for further processing. The sheet may then be washed to remove debris from the punching operation. A layer of photolithographic resist material may then be laminated on both of the metal layers. Next, the resist layer may be exposed to radiation in a suitable pattern to form the vias 32 (FIG. 1), and the resulting image may then be developed. A suitable protective coating may be laid down at the edges of the sheet to protect the sprocket holes from etching. Etching of the metal layers at the loci of the vias may then proceed.

After etching, the resist may be stripped from both sides of the sheet, and then the vias may be opened by laser drilling through the organic material. There then follows a stage in which the via holes are cleaned. Next is an initial metallization of the via holes, followed by copper plating to fill the via holes. Another cleaning stage removes residue left by the plating stage. Next, mechanical polishing is applied to roughen the copper layers.

Once again, a layer of photolithographic resist is laminated to both metal layers. Then the resist on each side of the sheet is exposed to radiation to form suitable patterns to produce the signal traces 22 and pads 24, 26 on one side of the sheet and to produce the ground plane 28 and pads 30 on the other side of the sheet. After developing the exposed resist, etching is performed on both sides, resulting in the aforesaid signal traces 22 and pads 24, 26 on one side of the sheet and ground plane 28 and pads 30 on the other side of the sheet. Excess resist is then stripped from both sides of the sheet.

There follows chemical pre-treatment in preparation for formation of a solder mask (resist) layer on one or both sides of the sheet. In some embodiments, the package component 10 is to have solder mask only on side, i.e. the bottom, as shown in FIG. 1. In other embodiments, another solder mask layer, which is not shown, may also be provided on the top of the substrate 12. If this additional (“underdie”) solder mask layer is to be provided, then a suitable PSR is applied to the top surface (i.e., the signal side) of the sheet (over the signal trace pattern). The PSR is then pre-baked, exposed and developed.

Next, PSR may be laminated to the ground side (bottom surface 16) of the substrate 12. The ground side PSR may then be pre-baked, exposed, developed, and post-baked to form the solder mask layer 34. There follows curing by UV radiation of the signal side PSR (if present) and the ground side PSR.

At a following stage, exposed metal regions may be gold and nickel plated. Another post bake may next be performed. At this point, the punched coverlay blank may be laminated to the top surface 14 of the substrate 12, as indicated at 86 in FIG. 3. Slitting of the sheet into individual package components 10 may follow, and an inspection stage may be performed. Then solder may be paste-printed into the holes 44 in the coverlay 38 to perform the required filling of the vias in the coverlay 38 with metal 46.

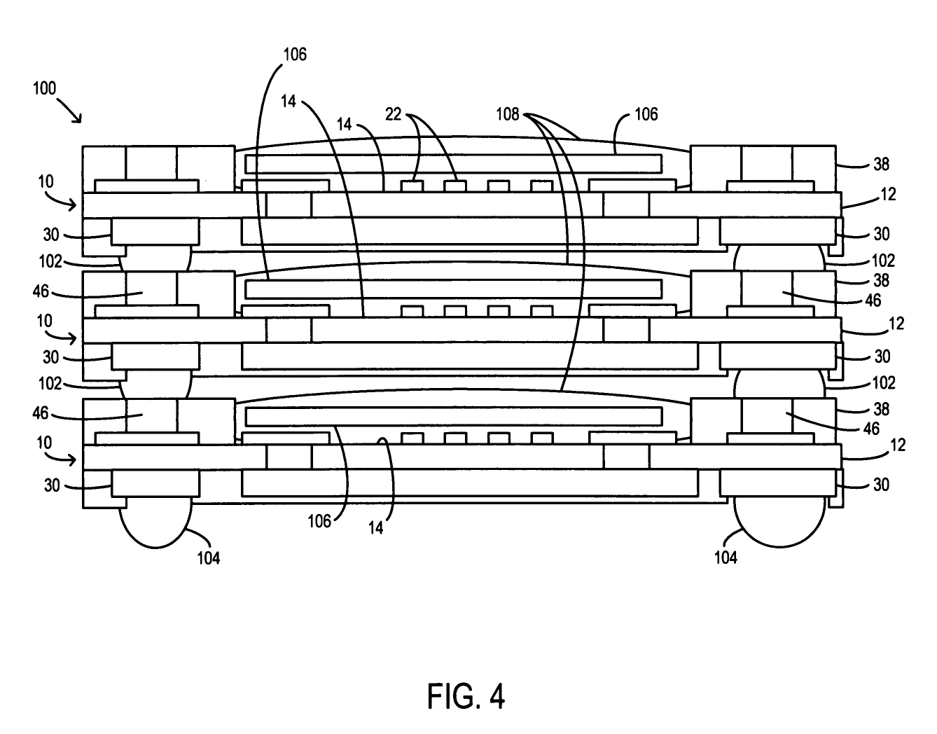

FIG. 4 is a schematic side cross-sectional view of a stacked IC package 100 according to some embodiments. The stacked IC package 100 incorporates several IC package components 10. The package components 10 may have been produced by either of the processes described above in connection with FIGS. 2 and 3. That is, at least some of the openings in the coverlays 38 may have been formed by photolithography or punching.

It will be observed from FIG. 4 that the package components 10 of the stacked package 100 are arranged in stacked relation to each other. Solder balls 102 provide conductive connections between the via metal 46 of a lower package component 10 to the metal pads 30 of an upper package component 10. Other solder balls 104 are provided on the metal pads 30 of the lowest package component 10 of the stack to facilitate connection of the stacked package 100 to a circuit board (not shown) or the like.

Each package component 10 has an IC 106 mounted on the top surface 14 of the substrate 12 of the respective package component 10. Semiconductor devices (not separately shown) on the ICs 106 may be coupled by connections which are not shown to the signal traces 22 on the substrate 12. Each of the ICs 106 on the lower package components 10 may be connected to the IC above by way of a conductive connection through the via metal 46 of the respective package component 10 and the corresponding solder ball 102 and pad 30 of the upper package component 10. Encapsulant 108 surrounds each of the ICs 106. It will be appreciated that, during application of the encapsulant 108, the coverlays 38 may provide boundaries limiting the flow of the encapsulant.

In some embodiments the ICs 106 may be of different types. For example, one IC may be a microprocessor (e.g., a microprocessor having a reduced number of input/output connections), a second IC may be a flash memory device, and a third IC may be RAM (random access memory).

Although three package components 10 (and thus three ICs 106) are shown in FIG. 4, the number of package components and ICs in the stacked package 100 may be two, or may be four or more.

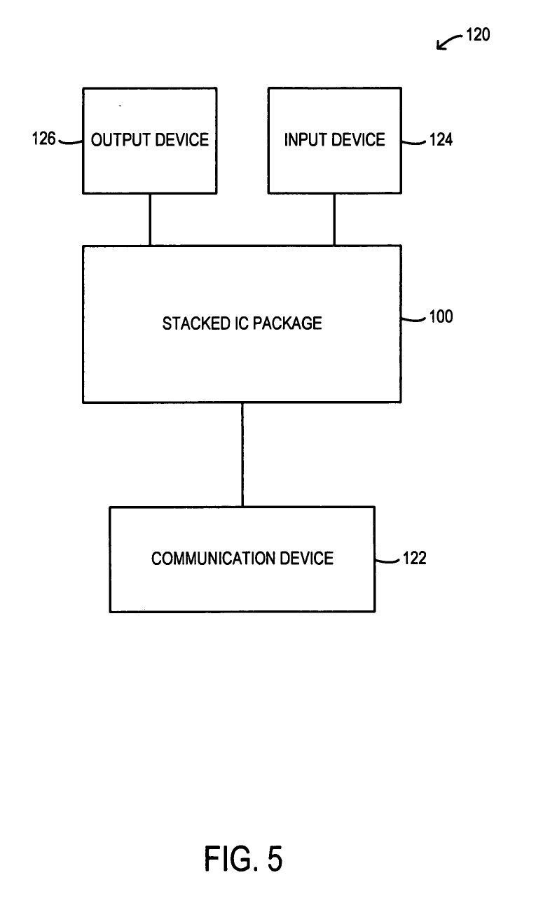

FIG. 5 is block diagram of an electronic apparatus 120 that includes the stacked IC package 100 shown in FIG. 4. The electronic apparatus 120 may also include a communication device 122 that is coupled to at least one IC (not separately shown in FIG. 5) of the stacked IC package 100. The communication device 122 may be, for example, an RF transceiver for a cellular telephone or a wireless transceiver for a PDA.

The electronic apparatus 120 may further include an input device 124 and an output device 126. The input device 124 and the output device 126 may be coupled to one or more of the ICs (e.g., a microprocessor) of the stacked IC package 100. The input device 124 may include, for example, a keyboard or keypad. The output device 126 may include a display. In some embodiments, the input and output devices may be combined in the form of a touch screen.

The electronic apparatus 120 may, in some embodiments, be a cellular telephone or a PDA, and may include other components which are not shown in the drawing. For example, the electronic apparatus may include a housing which contains or supports other components of the electronic apparatus, and the electronic apparatus may include a circuit board on which the stacked IC package 100 may be mounted.

In some embodiments, the coverlay 38 and the substrate 12 of the package components 10 may be of flexible, relatively thin material so that the stacked package formed from the package components may have a reduced height. Furthermore, the package components may be manufactured with coverlays in which openings are formed by photolithography or with flexible coverlays in which openings are punched. The manufacturing processes for the package components according to these embodiments may allow for an efficient flow of process stages and may be accomplished in a single manufacturing facility, so that manufacturing costs for the resulting stacked IC packages may be reduced.

The several embodiments described herein are solely for the purpose of illustration. The various features described herein need not all be used together, and any one or more of those features may be incorporated in a single embodiment. Therefore, persons skilled in the art will recognize from this description that other embodiments may be practiced with various modifications and alterations.

1. A method comprising:
providing a substrate;
providing a coverlay blank;
laminating the coverlay blank to the substrate; and
forming at least one opening in the coverlay blank by photolithography.

2. The method of claim 1, wherein the photolithography is performed after the laminating.

3. The method of claim 1, wherein the coverlay blank is of a flexible material.

4. The method of claim 3, wherein the substrate is of a flexible material.

5. The method of claim 1, wherein the coverlay blank includes at least one of acrylic, urethane and polyimide.

6. The method of claim 1, wherein:
the substrate has metal traces on a first surface of the substrate and a metal ground plane on a second surface of the substrate that is opposite to the first surface; and
the laminating includes laminating the coverlay blank to the first surface of the substrate.

7. The method of claim 6, wherein the metal traces and metal ground plane are of copper.

8. A product formed by the method of claim 1.

9. An article of manufacture, comprising:
a substrate; and
a coverlay laminated to the substrate and having at least one opening formed in the coverlay by photolithography.

10. The article of manufacture of claim 9, wherein the coverlay is of a flexible material.

11. The article of manufacture of claim 10, wherein the substrate is of a flexible material.

12. The article of manufacture of claim 9, wherein the coverlay includes at least one of acrylic, urethane and polyimide.

13. The article of manufacture of claim 9, wherein:
the substrate has metal traces on a first surface of the substrate and a metal ground plane on a second surface of the substrate that is opposite to the first surface; and
the coverlay is laminated to the first surface of the substrate.

14. The article of manufacture of claim 13, wherein the metal traces and metal ground plane are of copper.

15. An article of manufacture, comprising:
at least two integrated circuit (IC) packages in stacked relation to each other, each of the IC packages including:
a substrate;
an IC mounted on a surface of the substrate; and
a coverlay laminated on the surface of the substrate and having at least one opening formed by photolithography; and
at least one conductive connection formed through one of the coverlays and connecting one of the ICs to another of the ICs.

16. The article of manufacture of claim 15, wherein each IC is positioned in an opening of a respective one of the coverlays, the opening formed by photolithography.

17. The article of manufacture of claim 15, wherein the coverlays are of a flexible material.

18. The article of manufacture of claim 17, wherein the substrates are of a flexible material.

19. An apparatus comprising:
a stacked integrated circuit (IC) package which includes:
a first substrate;
a first IC mounted on a surface of the first substrate;
a first coverlay laminated on the surface of the first substrate and having at least one opening formed by photolithography;
a second substrate positioned in stacked fashion on the first coverlay;
a second IC mounted on a surface of the second substrate;
a second coverlay laminated on the surface of the second substrate and having at least one opening formed by photolithography; and
at least one conductive connection connecting the first IC to the second IC and passing through at least one opening in the first coverlay; and
a communication device coupled to at least one of the first IC and the second IC.

20. The apparatus of claim 19, wherein:
the first IC is positioned in an opening formed by photolithography in the first coverlay; and
the second IC is positioned in an opening formed by photolithography in the second coverlay.

21. The apparatus of claim 19, wherein the first and second coverlays are of a flexible material.

22. The apparatus of claim 21, wherein the first and second substrates are of a flexible material.

23. A method comprising:
providing a substrate;
providing a coverlay blank of a flexible material;
forming at least one opening in the coverlay blank by punching the coverlay blank; and
laminating the punched coverlay blank to the substrate.

24. The method of claim 23, wherein the substrate is of a flexible material.

25. The method of claim 23, wherein the coverlay blank includes at least one of acrylic, urethane and polyimide.

26. The method of claim 23, wherein:
the substrate has metal traces on a first surface of the substrate and a metal ground plane on a second surface of the substrate that is opposite to the first surface; and
the laminating includes laminating the punched coverlay blank to the first surface of the substrate.

27. The method of claim 26, wherein the metal traces and metal ground plane are of copper.

28. A product formed by the method of claim 23.

29. An article of manufacture, comprising:
a substrate; and
a coverlay of a flexible material, laminated to the substrate, and having at least one opening formed in the coverlay.

30. The article of manufacture of claim 29, wherein the substrate is of a flexible material.

31. The article of manufacture of claim 29, wherein the coverlay includes at least one of acrylic, urethane and polyimide.

32. The article of manufacture of claim 29, wherein:
the substrate has metal traces on a first surface of the substrate and a metal ground plane on a second surface of the substrate that is opposite to the first surface; and
the coverlay is laminated to the first surface of the substrate.

33. The article of manufacture of claim 32, wherein the metal traces and metal ground plane are of copper.

34. An article of manufacture, comprising:
at least two integrated circuit (IC) packages in stacked relation to each other, each of the IC packages including:
a substrate;
an IC mounted on a surface of the substrate; and
a coverlay of a flexible material laminated on the surface of the substrate and having at least one opening formed in the coverlay; and
at least one conductive connection formed through one of the coverlays and connecting one of the ICs to another of the ICs.

35. The article of manufacture of claim 34, wherein each IC is positioned in an opening of a respective one of the coverlays.

36. The article of manufacture of claim 34, wherein the substrates are of a flexible material.

37. An apparatus comprising:
a stacked integrated circuit (IC) package which includes:
a first substrate;
a first IC mounted on a surface of the first substrate;
a first coverlay of a flexible material laminated on the surface of the first substrate and having at least one opening formed in the first coverlay;
a second substrate positioned in stacked fashion on the first coverlay;
a second IC mounted on a surface of the second substrate;
a second coverlay of a flexible material laminated on the surface of the second substrate and having at least one opening formed in the second coverlay; and
at least one conductive connection connecting the first IC to the second IC and passing through at least one opening in the first coverlay; and
a communication device coupled to at least one of the first IC and the second IC.

38. The apparatus of claim 37, wherein:
the first IC is positioned in an opening in the first coverlay; and
the second IC is positioned in an opening in the second coverlay.

39. The apparatus of claim 37, wherein the first and second substrates are of a flexible material.
